(19) United States
(12) Patent Application Publication
(10) Pub. No.: US 2008/0179727 A1
(43) Pub. Date: Jul. 31, 2008

(54) SEMICONDUCTOR PACKAGES HAVING IMMUNITY AGAINST VOID DUE TO ADHESIVE MATERIAL AND METHODS OF FABRICATING THE SAME

(75) Inventors: Yong-Chai KWON, Gyeonggi-do (KR); Keum-Hee MA, Gyeongsangbuk-do (KR); Dong-Ho LEE, Gyeonggi-do (KR); Kang-Wook LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/852,930

(22) Filed: Sep. 10, 2007

(30) Foreign Application Priority Data
Jan. 25, 2007 (KR) 10-2007-0007940

(51) Int. Cl. H01L 23/02; H01L 21/00

(52) U.S. Cl. 257/686; 438/109; 257/E23.18

(57) ABSTRACT

Provided are semiconductor packages having immunity against a void due to an adhesive material and methods of fabricating the same. The semiconductor packages and the methods of fabricating the same can eliminate voids between package bodies to minimize delamination of the package bodies from the semiconductor package during the life time of semiconductor devices. To this end, a circuit substrate, a controller, and package bodies may be prepared. Each of the package bodies may have a package substrate, an adhesive pattern, and a package insulating layer. The package insulating layer may be formed on the package substrate to surround the adhesive pattern. The package bodies may be formed between the controller and the circuit substrate and contact the controller and the circuit substrate.

### CROSS-REFERENCE TO RELATED APPLICATIONS

This application claims priority under 35 USC § 119 to Korean Patent Application No. 10-2007-0007940, filed Jan. 25, 2007 in the Korean Intellectual Property Office, the contents of which are hereby incorporated herein by reference.

### BACKGROUND

1. Technical Field

The present invention relates to semiconductor packages and methods of fabricating the same and, more particularly, to semiconductor packages having immunity against a void due to an adhesive material and methods of fabricating the same.

2. Description of Related Art

Recently, semiconductor packages having 3-dimensionally laminated package bodies have been fabricated to meet the needs of small-sized and versatile electronic appliances. The package bodies each have semiconductor chips. Each of the semiconductor chips may be a volatile memory device and/or a nonvolatile memory device. In this case, the package bodies may form a semiconductor package by interposing an adhesive material therebetween. Since the package bodies are 3-dimensionally laminated in the semiconductor package, the area occupied by the package bodies in an electronic appliance can be reduced. Also, the package bodies may have a volatile memory device and/or a nonvolatile memory device according to the use of the electronic appliance so that the electronic appliance can be multifunctional.

However, the package bodies, which are mounted on the electronic appliance, may deteriorate the electrical characteristics of the semiconductor package during the life time of the electronic appliance due to the fact that the package bodies have the adhesive material therebetween to form the semiconductor package. In other words, due to the adhesive material, a void may be formed between the package bodies during a process of bonding the package bodies. The void is formed between the package bodies by compressing the adhesive material interposed between the package bodies. The void formed between the package bodies may result in the delamination of the package bodies during the life time of the electronic appliance. As a result, the void may detrimentally affect the semiconductor package and deteriorate the electrical characteristics of the electronic appliance.

Semiconductor chips having a structure similar to the package bodies are disclosed in Japanese Patent Laid-open Publication No. 2006-60067 by Tanida, et al. According to Japanese Patent Laid-open Publication No. 2006-60067, a plurality of semiconductor chips are prepared. The semiconductor chips have through electrodes. A resin encapsulant is interposed between the semiconductor chips to laminate the semiconductor chips. In this case, the through electrodes are brought into contact with one another through the semiconductor chips. In the above-described structure, the semiconductor chips and the through electrodes form semiconductor devices.

However, according to Japanese Patent Laid-open Publication No. 2006-60067, the semiconductor chips may be separated from one another in the semiconductor device because the resin encapsulant flows and is filled between the semiconductor chips. Thus, while flowing between the semiconductor chips, the resin encapsulant may define a void therebetween. The void defined between the semiconductor chips may separate the semiconductor chips from one another due to internal or external shocks during the life time of the semiconductor device. The present invention addresses these and other disadvantages of the conventional art.

### SUMMARY

An embodiment of the present invention provides semiconductor packages in which different kinds of adhesive materials are disposed between package bodies so that the semiconductor packages can have immunity against voids due to the adhesive materials disposed between the package bodies.

Another embodiment of the present invention provides methods of fabricating semiconductor packages in which different kinds of adhesive materials are formed between package bodies to eliminate voids due to the adhesive materials formed between the package bodies.

The present invention can improve the electrical characteristics of the semiconductor packages by preventing delamination of the package bodies from the semiconductor package during the life time of the semiconductor package.

### BRIEF DESCRIPTION OF THE DRAWINGS

Example embodiments of the present invention will become more apparent from the following detailed description taken in conjunction with the accompanying drawings. FIGS. 1-16 represent non-limiting example embodiments of the present invention as described herein.

FIG. 1 is a schematic view showing a semiconductor package according to an exemplary embodiment of the present invention.

FIGS. 2, 4, 6, 8, 10, 12, 14 and 15 are cross-sectional views illustrating a method of fabricating a semiconductor package taken along line I-I′ of FIG. 1 according to an exemplary embodiment of the present invention.

FIGS. 3, 5, 7, 9, 11, 13 and 16 are cross-sectional views illustrating a method of fabricating a semiconductor package taken along line II-II′ of FIG. 1 according to an exemplary embodiment of the present invention.

### DETAILED DESCRIPTION

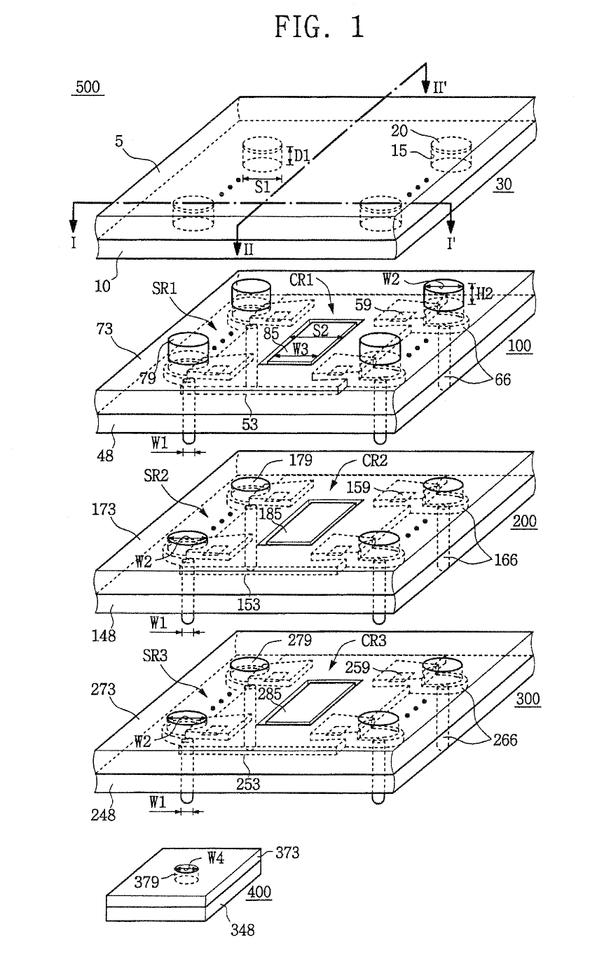

Semiconductor packages having immunity against a void formation due to an adhesive material according to exemplary embodiments of the present invention will now be described with reference to FIG. 1.

FIG. 1 is a schematic view showing a semiconductor device according to an exemplary embodiment of the present invention.

Referring to FIG. 1, a semiconductor package 500 comprises a first package body 100 and a circuit substrate 30. The circuit substrate 30 may have a base plate 5 and a base insulating layer 10. The base insulating layer 10 may be an adhesive material. The base insulating layer 10 may also be an insulating layer having an adhesive material. The base plate 5 may be a printed circuit board (PCB) that is known to one skilled in the art. The base plate 5 may be an insulating layer having a semiconductor integrated circuit (IC).

The base insulating layer 10 may define guide holes 15 exposing the base plate 5. The guide holes 15 of the base insulating layer 10 may be disposed on a peripheral region of the base plate 5. Each of the guide holes 15 may be formed to have a predetermined diameter S1 and a predetermined depth D1 in the base insulating layer 10. Connection layers 20 may be disposed in the base insulating layer 10. The connection layers 20 may be disposed in the guide holes 15, respectively. The connection layers 20 may be electrically connected to the base plate 5 through the guide holes 15.

Meanwhile, the first package body 100 may be disposed under the circuit substrate 30. In this case, the circuit substrate 30 may have the base insulating layer 10 and the base plate 5, which are sequentially laminated, and be disposed on the first package body 100. The first package body 100 may have a first package substrate 48, a first package insulating layer 73, and a first adhesive pattern 85. The first adhesive pattern 85 may have a predetermined width W3. The first package insulating layer 73 may be an adhesive material. The first package insulating layer 73 may be an insulating layer having an adhesive material. The first package insulating layer 73 may be a different material from the base insulating layer 10. Alternatively, the first package insulating layer 73 may be the same material as the base insulating layer 10. The first package insulating layer 73 may have a predetermined diameter S2 and surround the first adhesive pattern 85.

The first adhesive pattern 85 may be a different material from the first package insulating layer 73. Alternatively, the first adhesive pattern 85 may be the same material as the first package insulating layer 73. The first package insulating layer 73 and the first adhesive pattern 85 may be disposed on the first package substrate 48 and brought into contact with the base insulating layer 10. The first package substrate 48 may be divided into a first chip region CR1 and a first scribe region SR1.

The first scribe region SR1 may surround the first chip region CR1. The first chip region CR1 may have a first semiconductor chip 53. The first semiconductor chip 53 may be a volatile memory device and/or a nonvolatile memory device. The first semiconductor chip 53 may have first pad layers 59. The first pad layers 59 may be a conductive material. The first pad layers 59 may be electrically connected to the first semiconductor chip 53. In this case, the first adhesive pattern 85 may be disposed in a substantially central region of the first semiconductor chip 53.

The first package substrate 48 may have first via interconnections 66, and the first package insulating layer 73 may have first plugs 79. The first via interconnections 66 and the first plugs 79 may be a conductive material. The first via interconnections 66 may be prepared in a number equal to the number of the guide holes 15, and the first plugs 79 may also be prepared in a number equal to the number of the guide holes 15. The first via interconnections 66 and the first plugs 79 may be disposed in the first scribe region SR1 such that they are disposed adjacent to the first semiconductor chip 53.

The first via interconnections 66 may be electrically connected to the first semiconductor chip 53 and the first plugs 79. To this end, the first via interconnections 66 may be respectively in contact with the first pad layers 59 of the first semiconductor chip 53. The first via interconnections 66 may be exposed from the first package substrate 48. Each of the first via interconnections 66 may protrude with a predetermined width W1 from the first package substrate 48. Each of the first plugs 79 may penetrate the first package insulating layer 73 and protrude with a predetermined width W2 and a predetermined height H2 from the first package insulating layer 73. The first plugs 79 may contact the connection layers 20 through the guide holes 15 of the base insulating layer 10, respectively. As such, the first package body 100 may be electrically connected to the circuit substrate 30.

Referring again to FIG. 1, the semiconductor package 500 further comprises a second package body 200. The second package body 200 may be disposed under the first package body 100 in the semiconductor package 500. In this case, the first package body 100 may have the first package substrate 48 and the first package insulating layer 73, which are laminated sequentially, and be disposed on the second package body 200. The second package body 200 may have a second package substrate 148, a second package insulating layer 173, and a second adhesive pattern 185. The second adhesive pattern 185 may have the same width W3 as the first adhesive pattern 85. The second package insulating layer 173 may be formed of an adhesive material. The second package insulating layer 173 may be an insulating layer having an adhesive material. The second package insulating layer 173 may have the same diameter S2 as the first package insulating layer 73 and surround the second adhesive pattern 185. The second package insulating layer 173 may be the same material as the first package insulating layer 73. Alternatively, the second package insulating layer 173 may be formed of a different material from the first package insulating layer 73.

The second adhesive pattern 185 may be a different material from the second package insulating layer 173. Alternatively, the second adhesive pattern 185 may be the same material as the second package insulating layer 173. The second adhesive pattern 185 may be a different material from the first adhesive pattern 85. Alternatively, the second adhesive pattern 185 may be the same material as the first adhesive pattern 85. The second package insulating layer 173 and the second adhesive pattern 185 may be disposed on the second package substrate 148 and brought into contact with the first package substrate 48. The second package substrate 148 may be divided into a second chip region CR2 and a second scribe region SR2. The second scribe region SR2 may surround the second chip region CR2. The second chip region CR2 may have a second semiconductor chip 153. The second semiconductor chip 153 may be a volatile memory device and/or a nonvolatile memory device. The second semiconductor chip 153 may have second pad layers 159. The second pad layers 159 may be a conductive material. The second pad layers 159 may be electrically connected to the second semiconductor chip 153. In this case, the second adhesive pattern 185 may be disposed in a substantially central region of the second semiconductor chip 153.

The second package substrate 148 may have second via interconnections 166, and the second package insulating layer 173 may have second plugs 179. The second via interconnections 166 and the second plugs 179 may be a conductive material. The second via interconnections 166 may be prepared in a number equal to the number of the first via interconnections 66, and the second plugs 179 also may be prepared in a number equal to the number of the first via interconnections 66. The second via interconnections 166 and the second plugs 179 may be disposed in the second scribe region SR2 such that they are disposed adjacent to the second semiconductor chip 153.

The second via interconnections 166 may be electrically connected to the second semiconductor chip 153 and the second plugs 179. To this end, the second via interconnections 166 may be in contact with the second pad layers 159, respectively, of the second semiconductor chip 153. The second via interconnections 166 may be exposed from the second package substrate 148. Each of the second via interconnections 166 may have the same width W1 as the first via interconnections 66 and protrude from the second package substrate 148. Each of the second plugs 179 may penetrate the second package insulating layer 173 and be exposed by a predetermined width W2 in the second package insulating layer 173. The second plugs 179 may contact the first via interconnections 66, respectively. In this way, the second package body 200 may be electrically connected to the first package body 100.

Referring again to FIG. 1, a third package body 300 may be disposed under the second package body 200. In this case, the second package body 200 may have the second package substrate 148 and the second package insulating layer 173, which are laminated sequentially, and be disposed on the third package body 300. The third package body 300 may have a third package substrate 248, a third package insulating layer 273, and a third adhesive pattern 285. The third adhesive pattern 285 may have the same width W3 as the second adhesive pattern 185. The third package insulating layer 273 may be an adhesive material. The third package insulating layer 273 may be an insulating layer having an adhesive material. The third package insulating layer 273 may have the same diameter S2 as the second package insulating layer 173 and surround the third adhesive pattern 285. The third package insulating layer 273 may be the same material as the second package insulating layer 173. Alternatively, the third package insulating layer 273 may be a different material from the second package insulating layer 173.

The third adhesive pattern 285 may be a different material from the third package insulating layer 273. Alternatively, the third adhesive pattern 285 may be the same material as the third package insulating layer 273. The third adhesive pattern 285 may be a different material from the second adhesive pattern 185. Alternatively, the third adhesive pattern 285 may be the same material as the second adhesive pattern 185. The third package insulating layer 273 and the third adhesive pattern 285 may be disposed on the third package substrate 248 and brought into contact with the second package substrate 148. The third package substrate 248 may be divided into a third chip region CR3 and a third scribe region SR3. The third scribe region SR3 may surround the third chip region CR3. The third chip region CR3 may have a third semiconductor chip 253. The third semiconductor chip 253 may be a volatile memory device and/or a nonvolatile memory device. The third semiconductor chip 253 may have third pad layers 259. The third pad layers 259 may be a conductive material. The third pad layers 259 may be electrically connected to the third semiconductor chip 253. In this case, the third adhesive pattern 285 may be disposed in a substantially central region of the third semiconductor chip 253.

The third package substrate 248 may have third via interconnections 266, and the third package insulating layer 273 may have third plugs 279. The third via interconnections 266 and the third plugs 279 may be a conductive material. The third via interconnections 266 may be prepared in a number equal to the number of the second via interconnections 166, and the third plugs 279 also may be prepared in a number equal to the number of the second via interconnections 166. The third via interconnections 266 and the third plugs 279 may be disposed in the third scribe region SR3 such that they are disposed adjacent to the third semiconductor chip 253.

The third via interconnections 266 may be electrically connected to the third plugs 279 and the third semiconductor chip 253. To this end, the third via interconnections 266 may be in contact with the third pad layers 259, respectively, of the third semiconductor chip 253. The third via interconnections 266 may be exposed in the third package substrate 248. Each of the third via interconnections 266 may protrude with a predetermined width W1 from the third package substrate 248. Each of the third plugs 279 may penetrate the third package insulating layer 273 and be exposed by a predetermined width W2 in the third package insulating layer 273. The third plugs 279 may contact the second via interconnections 166, respectively. As such, the third package body 300 may be electrically connected to the second package body 200.

Again referring back to FIG. 1, a controller 400 may be disposed under the third package body 300. The third package body 300 may have the third package substrate 248 and the third package insulating layer 273, which are laminated sequentially, and be disposed on the controller 400. The controller 400 may have a controller substrate 348 and a protective layer 373. In this case, the controller 400 may have the protective layer 373 and the controller substrate 348 that are sequentially laminated under the third package body 300. The protective layer 373 may be an adhesive material. The protective layer 373 may be an insulating layer having an adhesive material. The protective layer 373 may be the same material as the third package insulating layer 273. Alternatively, the protective layer 373 may be a different material from the third package insulating layer 273.

The protective layer 373 may be a different material from the third adhesive pattern 285. Alternatively, the protective layer 373 may be the same material as the third adhesive pattern 285. The controller substrate 348 may be a semiconductor substrate having a semiconductor IC. Alternatively, the controller substrate 348 may be an insulating layer having a semiconductor IC. The protective layer 373 may have a connection node 379 disposed through the protective layer 373. The connection node 379 may be a conductive material. The connection node 379 may have a predetermined width W4 and be electrically connected to the controller substrate 348. The connection node 379 may be in contact with at least one of the third via interconnections 266. As such, the controller 400 may be electrically connected to the third package body 300. Furthermore, at least one additional package body (not shown) may be disposed between the controller 400 and the third package body 300. The additional package body may have substantially the same structure as the third package body 300 and be electrically connected to the third package body 300 and the controller 400.

According to some embodiments of the present invention, the first, second and third semiconductor chips may be different from each other in one or more of function and size. In other words, the first, second, and third semiconductor chips may have different lateral dimensions, such as width or length, and they may have different thicknesses. Also, the first, second, and third semiconductor chips may each have different functions, such as volatile and non-volatile memory functions and/or processor functions. When the first, second, and third semiconductor chips have different functions and/or sizes, the dimensions of the scribe regions and/or chip regions in the first, second and third package bodies may be adjusted to accommodate the different chips. Also, the thicknesses of the package insulating layers and the adhesive patterns may also be adjusted. Finally, according to some embodiments, the controller 400 may not be used in the semiconductor package of the present invention.

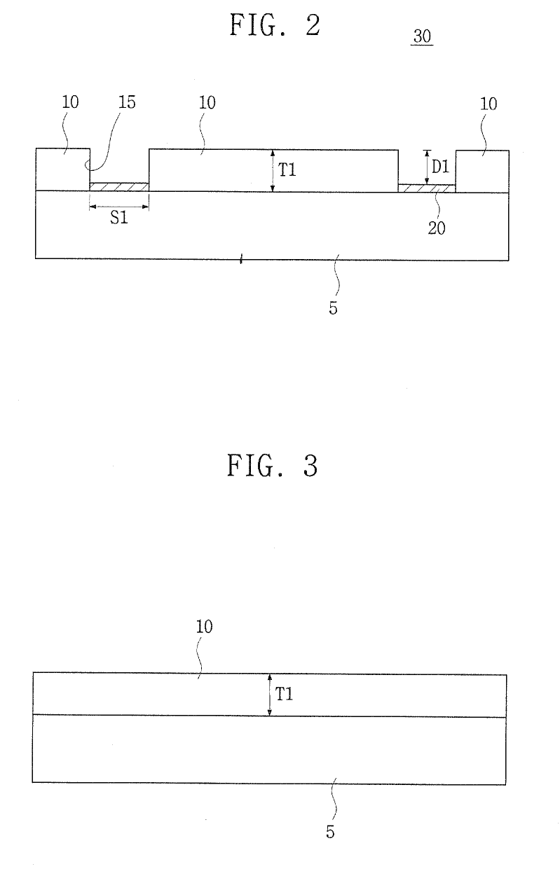

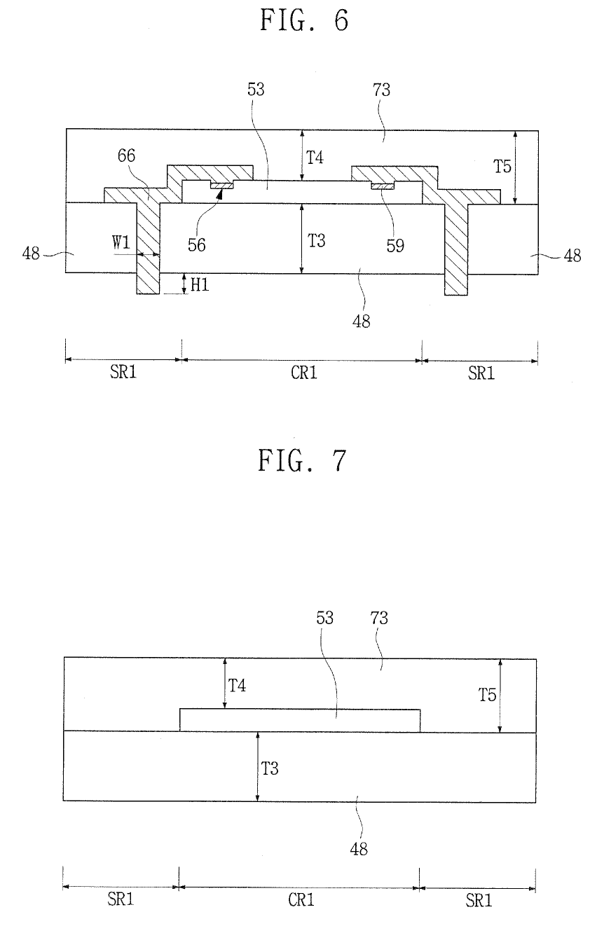

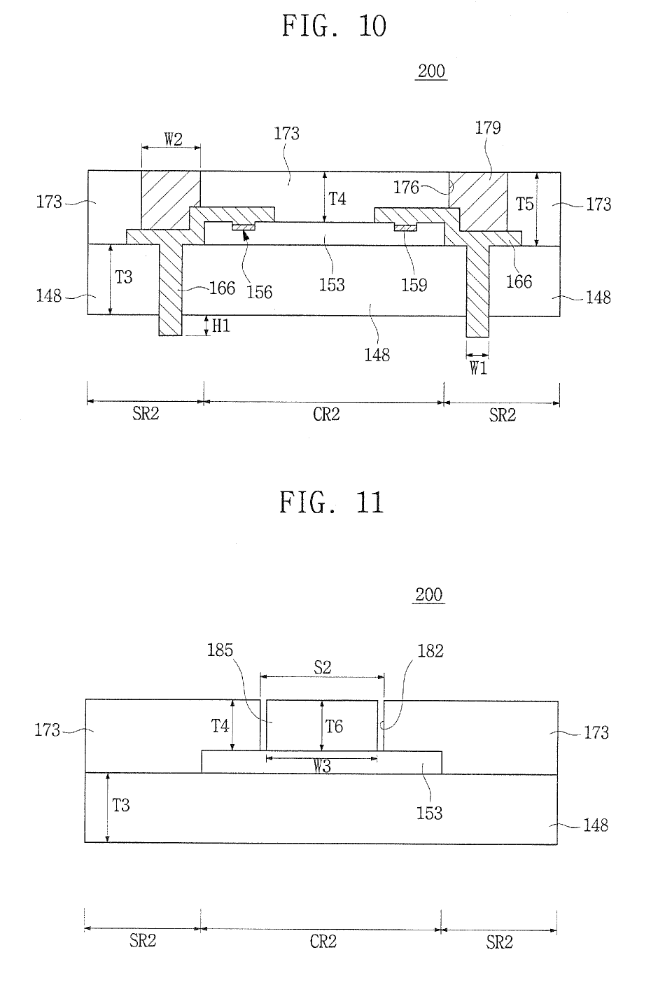

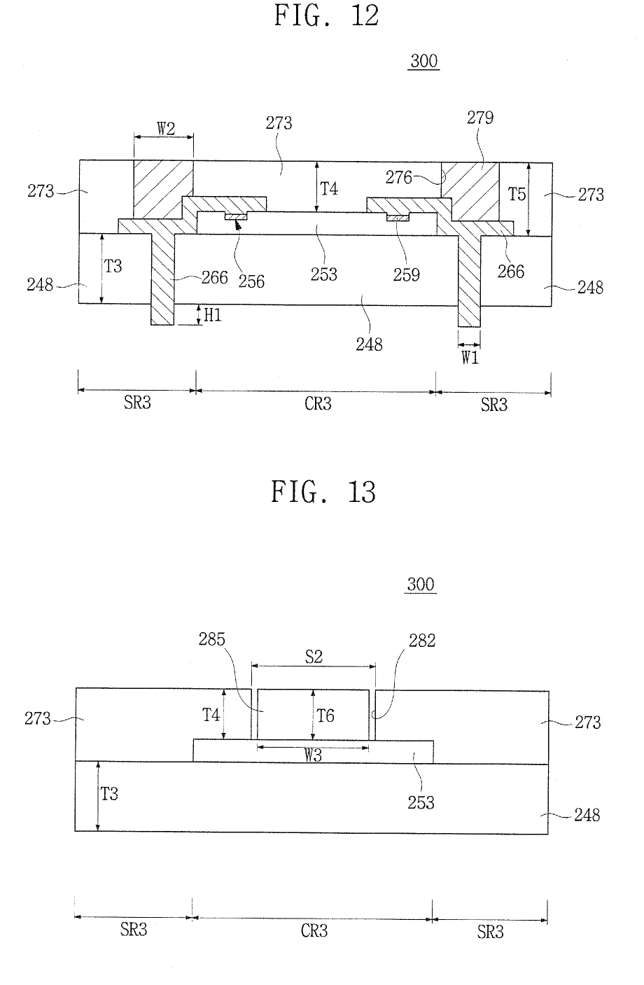

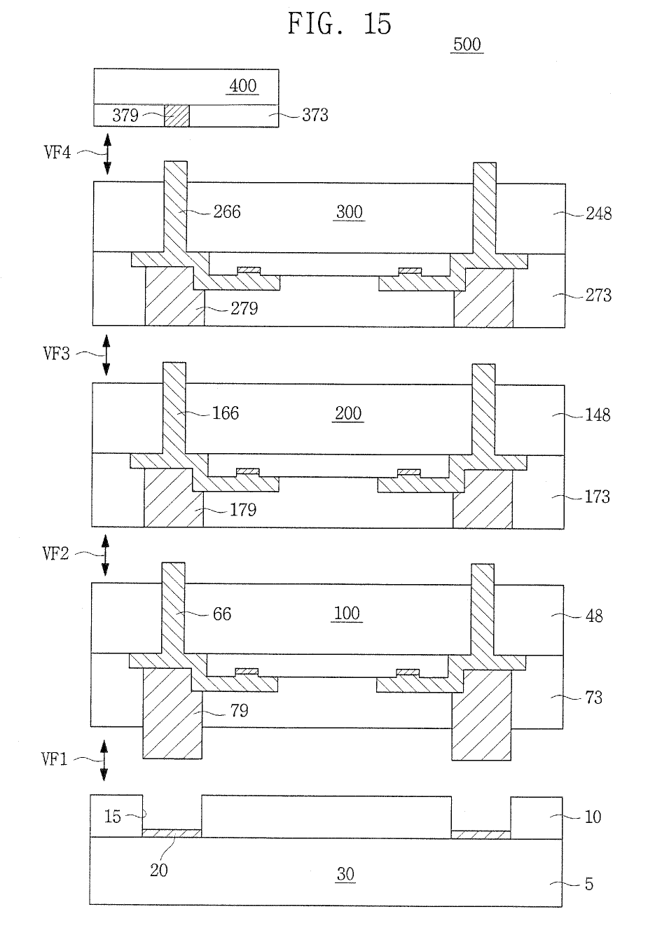

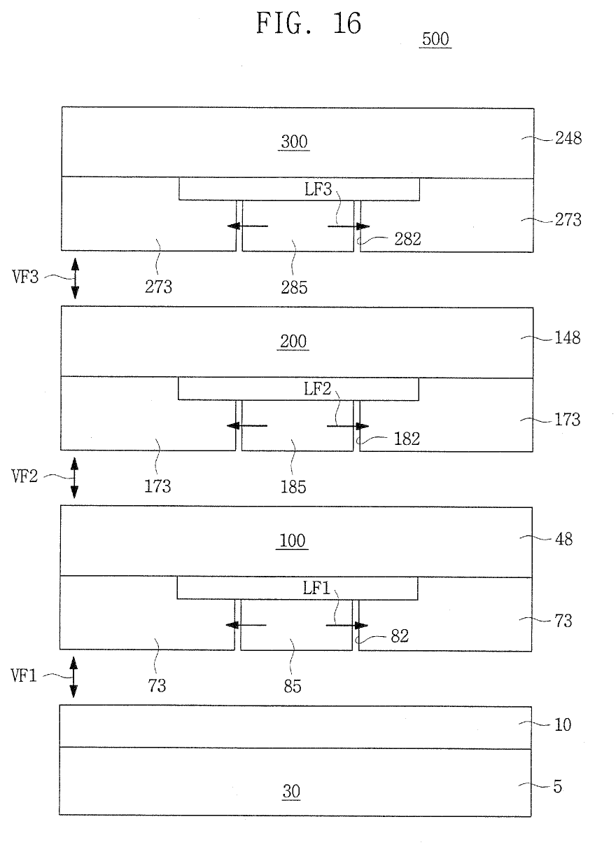

Hereinafter, methods of fabricating semiconductor packages having immunity against a void due to an adhesive material according to exemplary embodiments of the present invention will be described with reference to FIGS. 2 through 16.

FIGS. 2, 4, 6, 8, 10, 12, 14 and 15 are cross-sectional views illustrating a method of fabricating a semiconductor package taken along line I-I′ of FIG. 1 according to an exemplary embodiment of the present invention. FIGS. 3, 5, 7, 9, 11, 13 and 16 are cross-sectional views illustrating a method of fabricating a semiconductor package taken along line II-II′ of FIG. 1 according to an exemplary embodiment of the present invention.

Referring to FIGS. 1 through 3, a base plate 5 may be prepared. The base plate 5 may be formed of a PCB that is known to one skilled in the art. Alternatively, the base plate 5 may be formed of an insulating layer having a semiconductor IC. A base insulating layer 10 may be formed to a predetermined thickness T1 on the base plate 5. The base insulating layer 10 may be formed of an adhesive material. The base insulating layer 10 may be formed of an insulating layer having an adhesive material.

A photoresist layer may be formed on the base insulating layer 10. The photoresist layer may be obtained using a well known semiconductor photolithography process. The photoresist layer may be replaced by another material layer. The photoresist layer may be formed to have openings exposing the base insulating layer 10. The base insulating layer 10 may be etched using the photoresist layer as an etch mask, thereby forming guide holes 15 in the base insulating layer 11. The guide holes 15 may be formed to expose the base plate 5. The guide holes 15 may be formed on a peripheral region of the base plate 5.

After forming the guide holes 15, the photoresist layer may be removed from the base insulating layer 10. Connection layers 20 may be formed in the guide holes 15, respectively. The connection layers 20 may be formed of a conductive material. The connection layers 20 may be formed of, for example, copper (Cu) or aluminum (Al). Each of the guide holes 15 may be formed to have a predetermined diameter S1 and a predetermined depth D1 after forming the connection layer 20. The base insulating layer 10, the guide holes 15 and the connection layers 20 formed in the base insulating layer 10, and the base plate 5 may form a circuit substrate 30.

Referring to FIGS. 1, 4 and 5, a semiconductor substrate 44 may be prepared. The semiconductor substrate 44 may be formed of single crystalline silicon. The semiconductor substrate 44 may be a multi-layered material layer including a silicon on insulator (SOI) substrate. The semiconductor substrate 44 may be divided into a first chip region CR1 and a first scribe region SR1. The first scribe region SR1 may be formed to surround the first chip region CR1 as shown in FIG. 1. The first scribe region SR1 may have via holes 63. Each of the via holes 63 may be formed to have a predetermined depth D2 in the semiconductor substrate 44.

The semiconductor substrate 44 may have a first semiconductor chip 53 and first via interconnections 66. In this case, the first via interconnections 66 may be formed in the via holes 63, respectively, of the first scribe region SR1. The first via interconnections 66 may be formed in a number equal to the number of the guide holes 15 of FIG. 2. The first semiconductor chip 53 may be formed in the first chip region CR1. The first semiconductor chip 53 may be electrically connected to the semiconductor substrate 44, The first semiconductor chip 53 may be formed to a predetermined thickness T2 and protrude upward from a top surface of the semiconductor substrate 44. The first semiconductor chip 53 has first pad portions 56. The first semiconductor chip 53 may have first pad layers 59 in the first pad portions 56. The first pad layers 59 may be formed of a conductive material. The first via interconnections 66 may be electrically connected to the first semiconductor chip 53 through the first pad layers 59.

Referring to FIGS. 1, 6 and 7, a mask layer (not shown) may be formed on the semiconductor substrate 44 to cover the first semiconductor chip 53 and the first via interconnections 66. An etching process is performed on a surface of the semiconductor substrate 44, which is disposed opposite to a top surface of the mask layer. The etching process may be performed using an etchant having a higher etch rate with respect to the semiconductor substrate 44 than with respect to the first via interconnections 66. The etching process may be performed until the semiconductor substrate 44 has a predetermined thickness T3, so that a first package substrate 48 can be completed. At this time, the mask layer can protect the first semiconductor chip 53 and the first via interconnections 66 during the performance of the etching process. The first via interconnections 66 may be formed to have a predetermined width W1 and protrude to a predetermined height H1 from the first package substrate 48.

After etching the semiconductor substrate 44, the mask layer may be removed from the first package substrate 48. Subsequently, a first package insulating layer 73 may be formed on the first package substrate 48. The first package insulating layer 73 may be formed of an adhesive material. Alternatively, the first package insulating layer 73 may be formed of an insulating layer having an adhesive material. For example, the first package insulating layer 73 may be formed of one selected from the group consisting of phenol resin, epoxy resin, polyimide, benzocyclobutene (BCB), silicon, and polybenzooxydazole (PBO). The first package insulating layer 73 may be formed of a different material from the base insulating layer 10 of FIG. 1. Alternatively, the first package insulating layer 73 may be formed of the same material as the base insulating layer 10. At this time, the first package insulating layer 73 may be formed on the first semiconductor chip 53 and the first package substrate 48 to have predetermined thicknesses T4 and T5, respectively.

Referring to FIGS. 1, 8 and 9, a photoresist layer (not shown) may be formed on the first package insulating layer 73. The photoresist layer may be formed using a well known semiconductor photolithography process. The photoresist layer may be replaced by another material layer. The photoresist layer may be formed to have openings exposing the first package insulating layer 73. The first package insulating layer 73 may be etched using the photoresist layer as an etch mask, thereby forming first plug holes 76.

The first plug holes 76 may be formed to expose the first via interconnections 66, respectively. After forming the first plug holes 76, the photoresist layer may be removed from the first package insulating layer 73. First plugs 79 may be formed to fill the first plug holes 76, respectively. The first plugs 79 may be formed of a conductive material. The first plugs 79 may be formed of copper, aluminum, nickel solder and/or a combination thereof. The first plugs 79 may be formed to have a predetermined width W2 and protrude to a predetermined height H2 from the first package insulating layer 73.

Referring again to FIGS. 1, 8 and 9, a photoresist layer (not shown) may be formed on the first package insulating layer 73. The photoresist layer may be formed using a well known photolithography process. The photoresist layer may be replaced by another material layer. The first package insulating layer 73 may be etched using the photoresist layer as an etch mask, thereby forming a first insertion hole 82 in the first package insulating layer 73. The first insertion hole 82 may be formed to expose the first semiconductor chip 53 on the first package substrate 48. The first insertion hole 82 may be formed in the first package insulating layer 73 to have a predetermined diameter S2.

After forming the first insertion hole 82, the photoresist layer may be removed from the first package insulating layer 73. Then, a first adhesive pattern 85 may be formed to fill the insertion hole 82. The first adhesive pattern 85 may be formed of an adhesive material. Alternatively, the first adhesive pattern 85 may be formed of an insulating layer having an adhesive material. For example, the first adhesive pattern 85 may be formed of one selected from the group consisting of an anisotropic conductive film (ACF), a die-attach film (ADF), a non-conductive film (NCF), non-conductive paste (NCP), and epoxy resin. The first adhesive pattern 85 may be formed of a different material from the first package insulating layer 73. Alternatively, the first adhesive pattern 85 may be formed of the same material as the first package insulating layer 73. The first adhesive pattern 85 may be formed in the first insertion hole 82 so as to have a predetermined width W3.

The diameter S2 of the first insertion hole 82 may be greater in size than the width W3 of the first adhesive pattern 85. Alternatively, the diameter S2 of the first insertion hole 82 may be equal in size to the width W3 of the first adhesive pattern 85. A thickness T6 of the first adhesive pattern 85 may be equal to the thickness T4 of the first package insulating layer 73 formed on the first semiconductor chip 53. Alternatively, the thickness T6 of the first adhesive pattern 85 may be different from the thickness T4 of the first package insulating layer 73 formed on the first semiconductor chip 53. In a modified exemplary embodiment of the present invention, the process of forming the first adhesive pattern 85 may be followed by the process of forming the first plugs 79. As such, the first adhesive pattern 85, the first plugs 79, the first package insulating layer 73 and the first package substrate 48 can form a first package body 100.

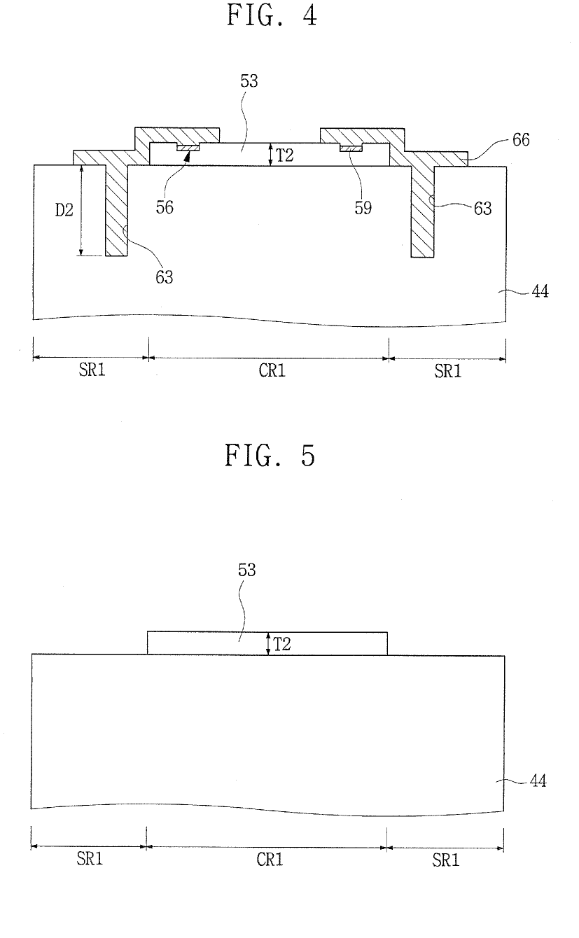

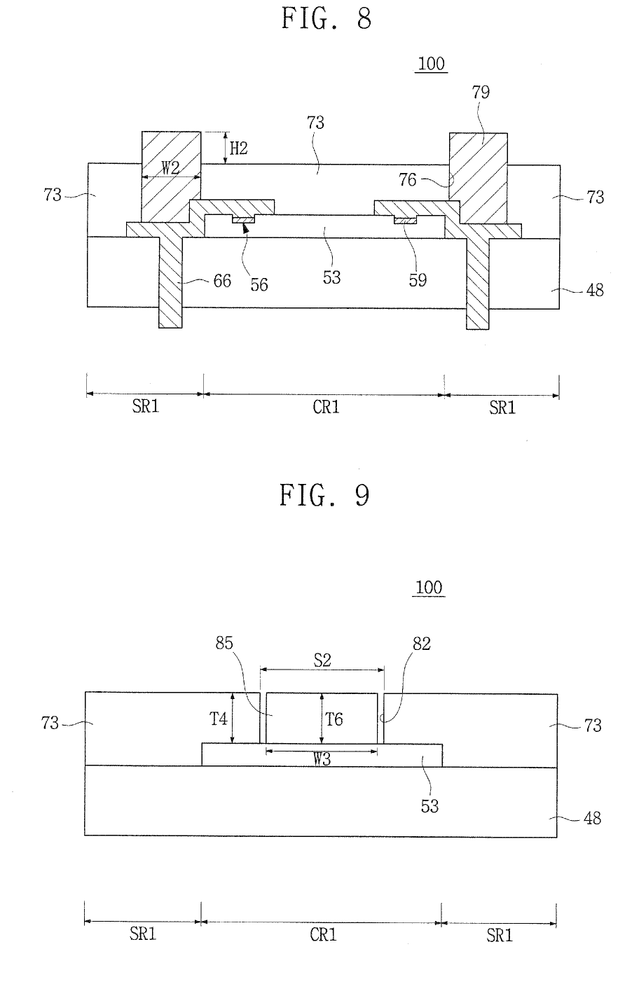

Referring to FIGS. 1, 10 and 11, a second package substrate 148 having a predetermined thickness T3 may be prepared. The second package substrate 148 may be formed using a semiconductor substrate 44 (refer to FIG. 4) like the first package substrate 48. The second package substrate 148 may be formed to have substantially the same structure as the first package substrate 48. Specifically, the second package substrate 148 may be divided into a second chip region CR2 and a second scribe region SR2. The second scribe region SR2 may be formed to have second via interconnections 166. The second via interconnections 166 may be formed in a number equal to the number of the first plugs 79 of FIG. 8. The second via interconnections 166 may be formed of a conductive material. The second chip region CR2 may be formed to have a second semiconductor chip 153. The second semiconductor chip 153 may be electrically connected to the second package substrate 148.

The second semiconductor chip 153 may be formed to have second pad portions 156. The second pad portions 156 may be formed to have second pad layers 159, respectively. The second pad layers 159 may be formed of a conductive material. Therefore, the second package substrate 148 may be formed by undergoing the same process as the process of forming the first package substrate 48 of FIG. 8. At this time, the second via interconnections 166 may be electrically connected to the second semiconductor chip 153 through the second pad layers 159. The second via interconnections 166 may be formed to have the width W1 and protrude to the height H1 from the second package substrate 148.

After preparing the second package substrate 148, a second package insulating layer 173 may be formed on the second package substrate 148. The second package insulating layer 173 may be formed of an adhesive material. Alternatively, the second package insulating layer 173 may be formed of an insulating layer having an adhesive material. For example, the second package insulating layer 173 may be one selected from the group consisting of phenol resin, epoxy resin, polyimide, BCB, silicon, and PBO. The second package insulating layer 173 may be formed of a different material from the first package insulating layer 73 of FIG. 8. Alternatively, the second package insulating layer 173 may be formed of the same material as the first package insulating layer 73. At this time, the second package insulating layer 173 may be formed on the second semiconductor chip 153 and the second package substrate 148 to have the thicknesses T4 and T5, respectively.

Referring again to FIGS. 1, 10 and 11, a photoresist layer (not shown) may be formed on the second package insulating layer 173. The photoresist layer may be formed using a well known semiconductor photolithography process. The photoresist layer may be replaced by another material layer. The photoresist layer may be formed to have openings exposing the second package insulating layer 173. The second package insulating layer 173 may be etched using the photoresist layer as an etch mask, thereby forming second plug holes 176.

The second plug holes 176 may be formed to expose second via interconnections 166, respectively. After forming the second plug holes 176, the photoresist layer may be removed from the second package insulating layer 173. Second plugs 179 may be formed to fill the second plug holes 176, respectively. The second plugs 179 may be formed of copper, aluminum, nickel, solder, and/or a combination thereof. The second plugs 179 may be formed to have the width W2 and so as to be exposed in the second package insulating layer 173. Again referring back to FIGS. 1, 10 and 11, a photoresist layer (not shown) may be formed on the second package insulating layer 173. The photoresist layer may be formed using a well known semiconductor photolithography process. The photoresist layer may be replaced by another material layer. The second package insulating layer 173 may be etched using the photoresist layer as an etch mask, thereby forming a second insertion hole 182 in the second package insulating layer 173. The second insertion hole 182 may be formed to expose the second semiconductor chip 153 on the second package substrate 148. The second insertion hole 182 may be formed in the second package insulating layer 173 to have the diameter S2.

After forming the second insertion hole 182, the photoresist layer may be removed from the second package insulating layer 173. A second adhesive pattern 185 may be formed to substantially fill the second insertion hole 182. The second adhesive pattern 185 may be formed of an adhesive material. Alternatively, the second adhesive pattern 185 may be formed of an insulating layer having an adhesive material. For example, the second adhesive pattern 185 may be formed of one selected from the group consisting of an ACF, a DAF, an NCF, NCP, and epoxy resin. The second adhesive pattern 185 may be formed of a different material from the second package insulating layer 173. Alternatively, the second adhesive pattern 185 may be formed of the same material as the second package insulating layer 173. The second adhesive pattern 185 may be formed in the second insertion hole 182 to have the width W3.

The diameter S2 of the second insertion hole 182 may be greater in size than the width W3 of the second adhesive pattern 185. Alternatively, the diameter S2 of the second insertion hole 182 may be equal in size to the width W3 of the second adhesive pattern 185. The thickness T6 of the second adhesive pattern 185 may be equal to the thickness T4 of the second package insulating layer 173 formed on the second semiconductor chip 153. Alternatively, the thickness T6 of the second adhesive pattern 185 may be different from the thickness T4 of the second package insulating layer 173 formed on the second semiconductor chip 153. In a modified exemplary embodiment of the present invention, the process of forming the second adhesive pattern 185 may be followed by the process of forming the second plugs 179. As such, the second adhesive pattern 185, the second plugs 179, the second package insulating layer 173 and the second package substrate 148 may form a second package body 200.

Referring to FIGS. 1, 12 and 13, a third package substrate 248 having a predetermined thickness T3 may be prepared. The third package substrate 248 may be formed using a semiconductor substrate 44 (refer to FIG. 4) like the first package substrate 48. The third package substrate 248 may be formed to have substantially the same structure as the second package substrate 148. Specifically, the third package substrate 248 may be divided into a third chip region CR3 and a third scribe region SR3.

The third scribe region SR3 may be formed to have third via interconnections 266. The third via interconnections 266 may be formed in a number equal to the number of the second plugs 179 of FIG. 10. The third via interconnections 266 may be formed of a conductive material. The third chip region CR3 may be formed to have a third semiconductor chip 253. The third semiconductor chip 253 may be electrically connected to the third package substrate 248.

The third semiconductor chip 253 may be formed to have third pad portions 256. The third pad portions 256 may be formed to have third pad layers 259, respectively. The third pad layers 259 may be formed of a conductive material. Therefore, the third package substrate 248 may be formed by undergoing the same process as the process of forming the second package substrate 148 of FIG. 10. At this time, the third via interconnections 266 may be electrically connected to the third semiconductor chip 253 through the third pad layers 259. The third via interconnections 266 may be formed to have the width W1 and protrude to the height H1 from the third package substrate 248.

After forming the third package substrate 248, a third package insulating layer 273 may be formed on the third package substrate 248. The third package insulating layer 273 may be formed of an adhesive material. Alternatively, the third package insulating layer 273 may be formed of an insulating layer having an adhesive material. For example, the third package insulating layer 273 may be one selected from the group consisting of phenol resin, epoxy resin, polyimide, BCB, silicon, and PBO. The third package insulating layer 273 may be formed of a different material from the second package insulating layer 173 of FIG. 10. Alternatively, the third package insulating layer 273 may be formed of the same material as the second package insulating layer 173. At this time, the third package insulating layer 273 may be formed on the third semiconductor chip 253 and the third package substrate 248 to have the thicknesses T4 and T5, respectively.

Referring again to FIGS. 1, 12 and 13, a photoresist layer (not shown) may be formed on the third package insulating layer 273. The photoresist layer may be formed using a well known semiconductor photolithography process. The photoresist layer may be replaced by another material layer. The photoresist layer may be formed to have openings exposing the third package insulating layer 273. The third package insulating layer 273 may be etched using the photoresist layer as an etch mask, thereby forming third plug holes 276.

Meanwhile, the third plug holes 276 may be formed to expose third via interconnections 266, respectively. After forming the third plug holes 276, the photoresist layer may be removed from the third package insulating layer 273. Third plugs 279 may be formed to fill the third plug holes 276, respectively. The third plugs 279 may be formed of copper, aluminum, nickel, solder, and/or a combination thereof. The third plugs 279 may be formed to have the width W2 and may be exposed in the third package insulating layer 273.

Again referring back to FIGS. 1, 12 and 13, a photoresist layer (not shown) may be formed on the third package insulating layer 273. The photoresist layer may be formed using a well known semiconductor photolithography process. The photoresist layer may be replaced by another material layer. The third package insulating layer 273 may be etched using the photoresist layer as an etch mask, thereby forming a third insertion hole 282 in the third package insulating layer 273. The third insertion hole 282 may be formed to expose the third semiconductor chip 253 on the third package substrate 248. The third insertion hole 282 may be formed in the third package insulating layer 273 to have the diameter S2.

After forming the third insertion hole 282, the photoresist layer may be removed from the third package insulating layer 273. A third adhesive pattern 285 may be formed to fill the third insertion hole 282. The third adhesive pattern 285 may be formed of an adhesive material. Alternatively, the third adhesive pattern 285 may be formed of an insulating layer having an adhesive material. For example, the third adhesive pattern 285 may be formed of one selected from the group consisting of an ACF, a DAF, an NCF, an NCP, and epoxy resin.

The third adhesive pattern 285 may be formed of a different material from the third package insulating layer 273. Alternatively, the third adhesive pattern 285 may be formed of the same material as the third package insulating layer 273. The third adhesive pattern 285 may be formed in the third insertion hole 282 to have the width W3. The diameter S2 of the third insertion hole 282 may be greater in size than the width W3 of the third adhesive pattern 285. Alternatively, the diameter S2 of the third insertion hole 282 may be equal in size to the width W3 of the third adhesive pattern 285.

The thickness T6 of the third adhesive pattern 285 may be equal to the thickness T4 of the third package insulating layer 273 formed on the third semiconductor chip 253. Alternatively, the thickness T6 of the third adhesive pattern 285 may be different from the thickness T4 of the third package insulating layer 273 formed on the third semiconductor chip 253. In a modified exemplary embodiment of the present invention, the process of forming the third adhesive pattern 285 may be followed by the process of forming the third plugs 279. As such, the third adhesive pattern 285, the third plugs 279, the third package insulating layer 273 and the third package substrate 248 may form a third package body 300.

Meanwhile, at least one additional package body (not shown) may be prepared under the third package body 300 along with the first through third package bodies 100, 200, and 300. The additional package body may be formed to have substantially the same structure as the second package body 200 or the third package body 300.

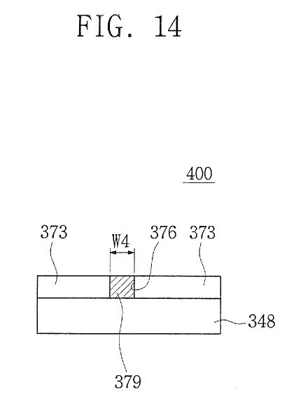

Referring to FIGS. 1 and 14, a controller substrate 348 may be prepared. The controller substrate 348 may be a semiconductor substrate having a semiconductor IC. The controller substrate 348 may be an insulating layer having a semiconductor IC. A protective layer 373 may be formed on the controller substrate 348. The protective layer 373 may be formed of an adhesive material. Alternatively, the protective layer 373 may be an insulating layer having an adhesive material. The protective layer 373 may be formed of a different material from the third package insulating layer 273 of FIG. 12. Alternatively, the protective layer 373 may be formed of the same material as the third package insulating layer 273. A photoresist layer (not shown) may be formed on the protective layer 373. The photoresist layer may be formed using a well known semiconductor photolithography process. The photoresist layer may be replaced by another material layer.

The photoresist layer may be formed to have openings exposing the protective layer 373. The protective layer 373 may be etched using the photoresist layer as an etch mask, thereby forming a connection hole 376 in the protective layer 373. After forming the connection hole 376, the photoresist layer may be removed from the protective layer 373. A connection node 379 may be formed to fill the connection hole 376. The connection node 379 may be formed of a conductive material. The connection node 379 may be formed of copper or aluminum. The connection node 379 may have a predetermined width W4 and be exposed in the protective layer 373. As such, the connection node 379, the protective layer 373 and the controller substrate 348 may form a controller 400. Also, the controller 400 may be formed under the at least one additional package body.

Referring to FIGS. 1, 15 and 16, the third package body 300, the second package body 200, the first package body 100, and the circuit substrate 30 may be sequentially formed under the controller 400. Also, the circuit substrate 30, the first package body 100, the second package body 200, the third package body 300, and the controller 400 can be brought into contact with one another. At this time, the connection node 379 of the controller 400 may be in contact with one selected out of the third via interconnections 266. The third plugs 279 of the third package body 300 may respectively contact the second via interconnections 166 of the second package body 200. The second plugs 179 of the second package body 200 may respectively contact the first via interconnections 66 of the first package body 100. Also, the first plugs 79 of the first package body 100 may be electrically connected to the circuit substrate 30 through the connection layers 20 formed in the guide holes 15 of the circuit substrate 30. As such, the circuit substrate 30 can be electrically connected to the controller 400 through the first through third package bodies 100, 200, and 300.

Meanwhile, in order to electrically connect the controller 400 to the circuit substrate 30, vertical physical forces VF1, VF2, VF3 and VF4 may be applied between the circuit substrate 30, the first through third package bodies 100, 200 and 300, and the controller 400. Thus, the protective layer 373 of the controller 400 may be brought into contact with the third package substrate 248 of the third package body 300, and the third package insulating layer 273 of the third package body 300 may be brought into contact with the second package substrate 148 of the second package body 200. The second package insulating layer 173 of the second package body 200 may be brought into contact with the first package substrate 48 of the first package body 100, and the first package insulating layer 73 of the first package body 100 may be brought into contact with the base insulating layer 10 of the circuit substrate 30.

Furthermore, in order to electrically connect the controller 400 to the circuit substrate 30, lateral physical forces LF1, LF2 and LF3 may be applied between internal portions of the first through third package bodies 100, 200 and 300 due to the vertical physical forces VF1, VF2, VF3 and VF4. Thus, the first adhesive pattern 85 of the first package body 100 may be brought into contact with the first package insulating layer 73 through the first insertion hole 82. The second adhesive pattern 185 of the second package body 200 may be brought into contact with the second package insulating layer 173 through the second insertion hole 182. Also, the third adhesive pattern 285 of the third package body 300 may be brought into contact with the third package insulating layer 273 through the third insertion hole 282.

During the application of the physical forces LF1, LF2, LF3, VF1, VF2, VF3 and VF4, the circuit substrate 30, the first through third package bodies 100, 200 and 300, and the controller 400 can eliminate voids caused by the base insulating layer 10, the first package insulating layer 73, the second package insulating layer 173, the third package insulating layer 273, and/or the protective layer 373 by means of the first insertion hole 82, the second insertion hole 182, and the third insertion hole 282. Also, the circuit substrate 30, the first through third package bodies 100, 200 and 300, and the controller 400 can form a semiconductor package 500 according to the present invention by applying the vertical physical forces VF1, VF2, VF3 and VF4 and the lateral physical forces LF1, LF2 and LF3. The semiconductor package 500 may have the at least one additional package body between the third package body 300 and the forth package body 400.

As described above, the present invention provides a semiconductor package having immunity against a void due to an adhesive material and a method of fabricating the same. Therefore, the present invention can improve the electrical characteristics of the semiconductor package by preventing delamination of the first through third package bodies from the semiconductor package during the life time of the semiconductor package.

An embodiment of the present invention provides semiconductor packages in which different kinds of adhesive materials are disposed between package bodies so that the semiconductor packages can have immunity against voids due to the adhesive materials disposed between the package bodies.

Another embodiment of the present invention provides methods of fabricating semiconductor packages in which different kinds of adhesive materials are formed between package bodies to eliminate voids due to the adhesive materials formed between the package bodies.

In one aspect, the present invention is directed to a semiconductor package comprising a circuit substrate. A first package body is electrically connected to the circuit substrate. The first package body has a first package substrate, a first adhesive pattern, and a first package insulating layer. The first package insulating layer and the first adhesive pattern are disposed under the first package substrate and contact the circuit substrate. The first package insulating layer surrounds the first adhesive pattern. A second package body is electrically connected to the first package body. The second package body has a second package substrate, a second adhesive pattern, and a second package insulating layer. The second package insulating layer and the second adhesive pattern are disposed under the second package substrate and contact the first package body. The second package insulating layer surrounds the second adhesive pattern. A controller is electrically connected to the second package body. The controller has a protective layer and a controller substrate that are laminated sequentially under the second package body.

In another aspect, the present invention is directed to a method of fabricating a semiconductor package having a controller substrate, a first package substrate, a second package substrate, and a base plate. A base insulating layer is formed on the base plate. The base insulating layer and the base plate form a circuit substrate. A first package insulating layer is formed on the first package substrate. The first package insulating layer has a first insertion hole exposing the first package substrate. A first adhesive pattern is formed to fill the first insertion hole of the first package insulating layer. The first adhesive pattern, the first package insulating layer, and the first package substrate form a first package body. A second package insulating layer is formed on the second package substrate. The second package insulating layer has a second insertion hole exposing the second package substrate. A second adhesive pattern is formed to fill the second insertion hole of the second package insulating layer. The second adhesive pattern, the second package insulating layer, and the second package substrate form a second package body. A protective layer is formed on the controller substrate. The protective layer and the controller substrate form a controller. The second package body, the first package body, and the circuit substrate are sequentially formed under the controller to connect the controller, the second package body, the first package body, and the circuit substrate to one another.

Exemplary embodiments of the present invention have been disclosed herein and, although specific terms are employed, they are used and are to be interpreted in a generic and descriptive sense only and not for the purpose of limitation. Accordingly, it will be understood by those of ordinary skill in the art that various changes in form and details may be made without departing from the spirit and scope of the present invention as set forth in the following claims.

What is claimed is:

1. A semiconductor package comprising:
a circuit substrate;
a first package body electrically connected to the circuit substrate and having a first package substrate, a first adhesive pattern, and a first package insulating layer, wherein the first package insulating layer and the first adhesive pattern are disposed under the first package substrate and contact the circuit substrate, and the first package insulating layer surrounds the first adhesive pattern;
a second package body electrically connected to the first package body and having a second package substrate, a second adhesive pattern, and a second package insulating layer, wherein the second package insulating layer and the second adhesive pattern are disposed under the second package substrate and contact the first package body, and the second package insulating layer surrounds the second adhesive pattern; and
a controller electrically connected to the second package body and having a protective layer and a controller substrate that are laminated sequentially under the second package body.

2. The semiconductor package according to claim 1, wherein the protective layer comprises a connection node electrically connected to the controller substrate.

3. The semiconductor package according to claim 2, wherein the second package substrate comprises a second chip region and a second scribe region, and the second chip region is surrounded by the second scribe region and has a second semiconductor chip.

4. The semiconductor package according to claim 3, wherein the second package substrate and the second package insulating layer comprise a second via interconnection and a second plug, respectively,
wherein the second via interconnection and the second plug are disposed in the second scribe region such that the second via interconnection and the second plug are disposed adjacent to the second semiconductor chip, the second adhesive pattern is disposed in a substantially central region of the second semiconductor chip, and the second via interconnection is electrically connected to the second plug and the second semiconductor chip and contacts the connection node.

5. The semiconductor package according to claim 4, wherein the first package substrate comprises a first chip region and a first scribe region,
wherein the first chip region is surrounded by the first scribe region and has a first semiconductor chip.

6. The semiconductor package according to claim 5, wherein the first package substrate and the first package insulating layer comprise a first via interconnection and a first plug, respectively,
wherein the first via interconnection and the first plug are disposed in the first scribe region such that the first via interconnection and the first plug are disposed adjacent to the first semiconductor chip, the first adhesive pattern is disposed in a substantially central region of the first semiconductor chip, and the first via interconnection is electrically connected to the first plug and the first semiconductor chip and contacts the second plug.

7. The semiconductor package according to claim 6, wherein the circuit substrate comprises a base plate and a base insulating layer,
wherein the base insulating layer has a guide hole exposing the base plate, and the first plug is in contact with the base plate through the guide hole.

8. The semiconductor package according to claim 7, further comprising: at least one additional package body disposed between the second package body and the controller, wherein the at least one additional package body has substantially the same structure as the second package body and is electrically connected to the second package body and the controller.

9. The semiconductor package according to claim 8, wherein each of the first and second plugs, the first and second via interconnections, and the connection node is formed of a conductive material.

10. The semiconductor package according to claim 9, wherein the base insulating layer, the first and second package insulating layers, and the protective layer are formed of the same material.

11. The semiconductor package according to claim 9, wherein the first and second adhesive patterns are formed of a different material from the base insulating layer, the first and second package insulating layers, and the protective layer.

12. The semiconductor package according to claim 11, wherein the first semiconductor chip and the second semiconductor chip are different from each other in one or more of size and function.

13. A method of fabricating a semiconductor package, comprising:
preparing a controller substrate, a first package substrate, a second package substrate, and a base plate;
forming a base insulating layer on the base plate, wherein the base insulating layer and the base plate form a circuit substrate;
forming a first package insulating layer on the first package substrate, wherein the first package insulating layer has a first insertion hole exposing a portion of the first package substrate;
forming a first adhesive pattern to fill the first insertion hole of the first package insulating layer, wherein the first adhesive pattern, the first package insulating layer, and the first package substrate form a first package body;
forming a second package insulating layer on the second package substrate, wherein the second package insulating layer has a second insertion hole exposing the second package substrate;
forming a second adhesive pattern to fill the second insertion hole of the second package insulating layer, wherein the second adhesive pattern, the second package insulating layer, and the second package substrate form a second package body;
forming a protective layer on the controller substrate, wherein the protective layer and the controller substrate form a controller; and
sequentially forming the second package body, the first package body, and the circuit substrate under the controller, to connect the controller, the second package body, the first package body, and the circuit substrate to one another.

14. The method according to claim 13, wherein the first package substrate comprises a first via interconnection and a first semiconductor chip,
wherein the first semiconductor chip protrudes upward from a top surface of the first package substrate, and the first via interconnection is electrically connected to the first semiconductor chip and exposed in a bottom surface of the first package substrate through the first package substrate.

15. The method according to claim 14, wherein the second package substrate comprises a second via interconnection and a second semiconductor chip,
wherein the second semiconductor chip protrudes upward from a top surface of the second package substrate, and the second via interconnection is electrically connected to the second semiconductor chip and exposed in a bottom surface of the second package substrate through the second package substrate.

16. The method according to claim 15, further comprising: after forming the base insulating layer,
forming a first photoresist layer on the base insulating layer, wherein the first photoresist layer is formed to have an opening exposing the base insulating layer;
forming a guide hole in the base insulating layer by etching the base insulating layer using the first photoresist layer as an etch mask; and
removing the first photoresist layer from the base insulating layer,
wherein the guide hole is formed to expose the base plate.

17. The method according to claim 16, further comprising: after forming the first adhesive pattern,
forming a second photoresist layer on the first package insulating layer, wherein the second photoresist layer is formed to have an opening exposing the first package insulating layer;
forming a first plug hole by etching the first package insulating layer using the second photoresist layer as an etch mask;
removing the second photoresist layer from the first package insulating layer; and
forming a first plug to fill the first plug hole in the first package insulating layer,
wherein the first plug is in contact with the first via interconnection, respectively.

18. The method according to claim 17, further comprising: after forming the second adhesive pattern,
forming a third photoresist layer on the second package insulating layer, wherein the third photoresist layer is formed to have an opening exposing the second package insulating layer;
forming a second plug hole by etching the second package insulating layer using the third photoresist layer as an etch mask;
removing the third photoresist layer from the second package insulating layer; and
forming a second plug to fill the second plug hole in the second package insulating layer,
wherein the second plug is in contact with the second via interconnection.

19. The method according to claim 18, further comprising: after forming the protective layer,
forming a fourth photoresist layer on the protective layer, wherein the fourth photoresist layer is formed to having an opening exposing the protective layer;
forming a connection hole by etching the protective layer using the fourth photoresist layer as an etch mask;
removing the fourth photoresist layer from the protective layer; and
forming a connection node to fill the connection hole in the protective layer,
wherein the connection node is electrically connected to the controller substrate.

20. The method according to claim 19, wherein contacting the controller, the second package body, the first package body, and the circuit substrate to one another comprises connecting the connection node, the second plugs, and the first plugs to the second via interconnection, the first via interconnection, and the circuit substrate, respectively.

21. The method according to claim 20, wherein the first adhesive pattern is formed on the first semiconductor chip adjacent to the first via interconnection and the first plug.

22. The method according to claim 21, wherein the second adhesive pattern is formed on the second semiconductor chip adjacent to the second via interconnection and the second plug.

23. The method according to claim 22, wherein each of the first and second plugs, the first and second via interconnections, and the connection node is formed of a conductive material.

24. The method according to claim 23, further comprising: forming at least one additional package body interposed between the controller and the second package body,
wherein the additional package body has substantially the same structure as the second package body and contacts the second package body and the controller.

25. The method according to claim 13, wherein the base insulating layer, the first and second package insulating layers, and the protective layers are formed of the same material.

26. The method according to claim 13, wherein the first and second adhesive patterns are formed of a different material from the base insulating layer, the first and second package insulating layers, and the protective layer.

27. A semiconductor package comprising:
a circuit substrate; and
a plurality of package bodies electrically connected to the circuit substrate, wherein each of the package bodies comprises:
a package substrate;
a semiconductor chip on the package substrate;
a package insulating layer on the package substrate and the semiconductor chip, wherein the package insulating layer comprises an insertion hole;
an adhesive pattern disposed in the insertion hole, the adhesive pattern configured to adhere each of the package bodies to an adjacent one of the package bodies;
via interconnections penetrating the package substrate, protruding from the package substrate, and electrically connected to the semiconductor chip; and
conductive plugs disposed on the via interconnections, the conductive plugs exposed on a surface of the package insulating layer.

28. The semiconductor package of claim 27, further comprising a controller electrically connected to the package bodies and having a protective layer and a controller substrate.

29. The semiconductor package of claim 27, wherein the circuit substrate comprises:
a base plate;
a base insulating layer on the base plate;
guide holes in the base insulating layer; and
connection layers in the guide holes.

30. The semiconductor package of claim 29, wherein the base plate is a printed circuit board (PCB), the base insulating layer comprises an adhesive material, and the connection layers are electrically connected to the base plate.

31. The semiconductor package of claim 30, wherein the circuit substrate is electrically connected to the package bodies by the connection layers, the conductive plugs, and the via interconnections.

32. The semiconductor package of claim 30, wherein the conductive plugs of one of the plurality of package bodies protrude above a surface of the package insulating layer and contact the connection layers in the guide holes of the circuit substrate.

33. The semiconductor package of claim 27, wherein the package insulating layers comprise a different material than the adhesive patterns.

34. The semiconductor package of claim 27, wherein at least one of the semiconductor chips in the plurality of package bodies is different in one or more of size and function from the remaining semiconductor chips.

35. The semiconductor package of claim 27, wherein the insertion holes are filled by the adhesive patterns such that no voids are disposed between the package bodies.
